(19) United States
(12) Patent Application Publication
(10) Pub. No.: US 2025/0187072 A1
(43) Pub. Date: Jun. 12, 2025

(54) ADDITIVELY MANUFACTURED ACOUSTIC BACKING WITH BUILT IN INFILTRATION MOLD

(71) Applicant: GE Precision Healthcare LLC, Waukesha, WI (US)

(72) Inventors: Caitlin Theresa Strobel, New Castle, PA (US); Jaroslaw Kurzac, Oconomowoc, WI (US); James Joseph Van Bogart, Pewaukee, WI (US); Christopher Michael Gabel, Waukesha, WI (US); Paul Michael Wervey, Mukwonago, WI (US); Yanju Wang, Hartland, WI (US); Nathan Zane Schlawin, Jackson, WI (US); Alexander Steel Yankowski, South Milwaukee, WI (US); Dulce Maria Colindres Mendoza, Milwaukee, WI (US)

(21) Appl. No.: 18/532,635

(22) Filed: Dec. 7, 2023

(51) Int. Cl. B22F 7/00; B22F 3/26; B22F 10/20; B22F 10/60; B33Y 10/00

(52) U.S. Cl. CPC B22F 7/004; B22F 3/26; B22F 10/20; B22F 10/60; B33Y 10/00

(57) ABSTRACT

A method for manufacturing an acoustic backing of a transducer probe is provided. The method includes utilizing three-dimensional (3D) printing to print a single part including both a porous structure and a solid structure, wherein the porous structure is disposed within the solid structure, and the porous structure is configured to attenuate acoustic energy. The method also includes infiltrating the single part with filler material. The method further includes curing the single part, wherein the single part is configured both to enable the filler material to enter the porous structure during infiltration and to keep the filler material contained in the porous structure between the infiltration and curing of the single part.

### BACKGROUND

The subject matter disclosed herein relates to additive manufacturing and, more particularly, additive manufacturing of an acoustic backing (e.g., for a transducer probe such as an ultrasound probe) with a built in infiltration mold.

Transducer probes are used in a variety of applications to convert energy from a physical form to an electrical form. For example, a transducer probe may include piezoelectric materials which may vibrate at a resonance frequency when a mechanical stress or strain is exerted on the materials. An acoustic signal may be generated by the vibrating piezoelectric materials which may be transmitted from a front end of the transducer probe. In order to absorb and attenuate acoustic energy scattered in directions away from the front end of the transducer probe, such as towards a rear end of the transducer probe, a backing may be included in an acoustic stack of the transducer probe. The backing may be arranged behind the piezoelectric materials, relative to a direction of signal propagation, and may be formed of materials that dampen the scattered acoustic energy, thereby reducing reverberation of the acoustic energy and mitigating interference with signal reception at the transducer probe.

### BRIEF DESCRIPTION

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In one embodiment, a method for manufacturing an acoustic backing of a transducer probe is provided. The method includes utilizing three-dimensional (3D) printing to print a single part including both a porous structure and a solid structure, wherein the porous structure is disposed within the solid structure, and the porous structure is configured to attenuate acoustic energy. The method also includes infiltrating the single part with filler material. The method further includes curing the single part, wherein the single part is configured both to enable the filler material to enter the porous structure during infiltration and to keep the filler material contained in the porous structure between the infiltration and curing of the single part.

In another embodiment, a method for manufacturing an acoustic backing of a transducer probe is provided. The method includes utilizing three-dimensional (3D) printing to print a single part including both a porous structure and a hybrid porous/solid structure, wherein the porous structure is disposed within the hybrid porous/solid structure, and the porous structure is configured to attenuate acoustic energy. The method also includes infiltrating the single part with filler material. The method further includes curing the single part, wherein the single part has variable porosity configured both to enable the filler material to enter the porous structure during infiltration and to keep the filler material contained in the porous structure between the infiltration and curing of the single part.

In a further embodiment, a method for manufacturing an acoustic backing of a transducer probe is provided. The method includes utilizing three-dimensional (3D) printing to print a single part including both a first porous structure and a second porous structure, wherein the first porous structure is disposed within the second porous structure, and the first porous structure is configured to attenuate acoustic energy. The method also includes infiltrating the single part with filler material. The method further includes curing the single part, wherein the single part has variable porosity configured both to enable the filler material to enter the first porous structure during infiltration and to contain the filler material in the first porous structure between the infiltration and curing of the single part.

### BRIEF DESCRIPTION OF THE DRAWINGS

These and other features, aspects, and advantages of the present subject matter will become better understood when the following detailed description is read with reference to the accompanying drawings in which like characters represent like parts throughout the drawings, wherein:

FIG. 1 is a block diagram of an ultrasound system, in accordance with aspects of the present disclosure;

FIG. 2 is schematic diagram of an ultrasound transducer having an additively manufactured acoustic backing, in accordance with aspects of the present disclosure;

FIG. 3 is a schematic diagram illustrating attenuation of acoustic energy in the additively manufactured acoustic backing, in accordance with aspects of the present disclosure;

FIG. 4 is a perspective view of an additively manufactured acoustic backing with a built in (e.g., integrated) infiltration mold, in accordance with aspects of the present disclosure;

FIG. 5 is cross-sectional view of an additively manufactured acoustic backing with a built in (e.g., integrated) infiltration mold (e.g., with mold having one side open), taken along line 5-5 in FIG. 4, in accordance with aspects of the present disclosure;

FIG. 6 is cross-sectional view of an additively manufactured acoustic backing with a built in (e.g., integrated) infiltration mold (e.g., with mold having one side open and internal passages), taken along line 5-5 in FIG. 4, in accordance with aspects of the present disclosure;

FIG. 7 is a flow chart of a method for manufacturing an acoustic backing with a built in (e.g., integrated) infiltration mold (e.g., with mold having one side open), in accordance with aspects of the present disclosure;

FIG. 8 is cross-sectional view of an additively manufactured acoustic backing with a built in (e.g., integrated) infiltration mold (e.g., with mold having one side porous), taken along line 5-5 in FIG. 4, in accordance with aspects of the present disclosure;

FIG. 9 is cross-sectional view of an additively manufactured acoustic backing with a built in (e.g., integrated) infiltration mold (e.g., with mold having two sides porous), taken along line 5-5 in FIG. 4, in accordance with aspects of the present disclosure;

FIG. 10 is a flow chart of a method for manufacturing an acoustic backing with a built in (e.g., integrated) infiltration mold (e.g., with mold having one or two porous sides), in accordance with aspects of the present disclosure;

FIG. 11 is cross-sectional view of an additively manufactured acoustic backing with a built in (e.g., integrated) infiltration mold (e.g., with mold having all sides porous), taken along line 5-5 in FIG. 4, in accordance with aspects of the present disclosure;

FIG. 12 is a flow chart of a method for manufacturing an acoustic backing with a built in (e.g., integrated) infiltration mold (e.g., with mold having all sides porous), in accordance with aspects of the present disclosure; and

FIG. 13 is cross-sectional view of an additively manufactured acoustic backing with a built in (e.g., integrated) infiltration mold (e.g., with mold having one side porous), taken along line 5-5 in FIG. 4, in accordance with aspects of the present disclosure;

FIG. 14 is cross-sectional view of an additively manufactured acoustic backing with a built in (e.g., integrated) infiltration mold (e.g., with mold having one side open) and a built-in fence to retain filler material and create a reservoir, in accordance with aspects of the present disclosure;

FIG. 15 is a cross-sectional view and a top view of an additively manufactured acoustic backing (e.g., having spacers), in accordance with aspects of the present disclosure;

FIG. 16. is a cross-sectional view of an additively manufactured acoustic backing (e.g., with a space between the mold and porous structure), in accordance with aspects of the present disclosure.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present subject matter, the articles “a,” “an,” “the,” and “said” are intended to mean that there are one or more of the elements. The terms “comprising,” “including,” and “having” are intended to be inclusive and mean that there may be additional elements other than the listed elements. Furthermore, any numerical examples in the following discussion are intended to be non-limiting, and thus additional numerical values, ranges, and percentages are within the scope of the disclosed embodiments.

Some generalized information is provided to provide both general context for aspects of the present disclosure and to facilitate understanding and explanation of certain of the technical concepts described herein.

As used herein, the term “image” broadly refers to both viewable images and data representing a viewable image. However, many embodiments generate (or are configured to generate) at least one viewable image. In addition, as used herein, the phrase “image” is used to refer to an ultrasound mode such as B-mode (2D mode), M-mode, three-dimensional (3D) mode, CF-mod014e, PW Doppler, CW Doppler, MGD, and/or sub-modes of B-mode and/or CF such as Shear Wave Elasticity Imaging (SWEI), TVI, Angio, B-flow, BMI, BMI_Angio, and in some cases also MM, CM, TVD where the “image” and/or “plane” includes a single beam or multiple beams.

Furthermore, the term processor or processing unit, as used herein, refers to any type of processing unit that can carry out the required calculations needed for the various embodiments, such as single or multi-core: CPU, Accelerated Processing Unit (APU), Graphics Board, DSP, FPGA, ASIC or a combination thereof.

Manufacturing of acoustic backings having a porous structure (or porous matrix) filled with filler material (e.g., lossy epoxy) is difficult. Upon additively manufacturing the acoustic backing, it is infiltrated with filler material to produce a final part with high attenuation and good conductivity. However, if the acoustic backing is not fully infiltrated, pockets of air in the acoustic backing can create defects that will either result in a transducer being scrapped or, if not detected during manufacturing, a transducer that creates noise during a scan (e.g., ultrasound scan). The difficulty is keeping filler material within the acoustic backing during infiltration. Indeed, manufacturing a fully infiltrated acoustic backing is cumbersome and not easily translatable into production.

The present disclosure provides methods for manufacturing (e.g., additively manufacturing) an acoustic backing of a transducer probe (e.g., an ultrasound probe). In particular, the disclosed embodiments enable the additive manufacturing (e.g., three-dimensional (3D) printing) of an acoustic backing with integrated or built in mold as a single part. The single part is a multi-parameter backing that includes an acoustic attenuation parameter set (i.e., the acoustic backing portion having a porous structure or matrix) and a parameter set with high density but some porosity (in some cases) (i.e., the mold and/or fence). The single part or multi-parameter backing enables filler material (e.g., lossy epoxy) to enter the porous structure during infiltration and to remain within the porous structure between infiltration and curing. This approach also enables the addition of a fence to create a reservoir to ensure adequate filler material is available to fill pores and account for material shrinkage. The disclosed embodiments enable the utilization of an industrial infiltration system in manufacturing the acoustic backing. In addition, the disclosed embodiments improve the quality of the additively manufactured acoustic backing. Further, the disclosed embodiments reduce the amount of scrap generated in additively manufacturing acoustic backings (e.g., due to void spaces in the additively manufactured acoustic backings). Even further, the disclosed embodiments enable the additive manufacturing of the acoustic backings to reduce the chance of a supply chain risk.

In one embodiment, the method includes utilizing three-dimensional (3D) printing to print a single part including both a porous structure and a solid structure, wherein the porous structure is disposed within the solid structure, and the porous structure is configured to attenuate acoustic energy. The method also includes infiltrating the single part with filler material. The method further includes curing the single part, wherein the single part is configured both to enable the filler material to enter the porous structure during infiltration and to keep the filler material contained in the porous structure between the infiltration and curing of the single part. In certain embodiments, the method further includes removing the solid structure from the porous structure to obtain the acoustic backing. In certain embodiments, the porous structure includes multiple surfaces and the solid structure covers all but one surface of the multiple surfaces of the porous structure leaving the one surface exposed. In certain embodiments, the solid structure includes one or more passages extending from an exposed surface of the solid structure to one or more surfaces of the multiple surfaces of the porous structure, and the one or more passages are configured to enable the filler material and/or an un-sintered metallic powder to enter the porous structure via the one or more surfaces during infiltration. In certain embodiments, the single part (the porous structure and/or the mold) has a complex geometric shape. In certain embodiments, the built-in mold extends beyond the porous structure (fence) to create a reservoir for filler material.

In one embodiment, the method includes utilizing three-dimensional (3D) printing to print a single part including both a porous structure and a hybrid porous/solid structure, wherein the porous structure is disposed within the hybrid porous/solid structure, and the porous structure is configured to attenuate acoustic energy. The method also includes infiltrating the single part with filler material. The method further includes curing the single part, wherein the single part has variable porosity configured both to enable the filler material to enter the porous structure during infiltration and to keep the filler material contained in the porous structure between the infiltration and curing of the single part. In certain embodiments, the method further includes removing the hybrid porous/solid structure from the porous structure to obtain the acoustic backing. In certain embodiments, the porous structure includes multiple surfaces and the hybrid porous/solid structure includes both a porous portion and a solid portion, and wherein the solid portion of the hybrid porous/solid structure covers all but one surface of the multiple surfaces of the porous structure, and the porous portion of the hybrid porous/solid structure covers the one surface of the porous structure not covered by the solid portion of the hybrid porous/solid structure. In certain, embodiments (with one surface covered by the solid portion), a portion of the solid portion of the hybrid porous/solid structure covering the one surface of the porous structure is thinner than the porous structure. In certain embodiments (with one surface covered by a thin, solid portion), pores of the thin, solid portion of the hybrid porous/solid structure are smaller than pores of the porous structure. In certain embodiments, the porous structure includes multiple surfaces and the hybrid porous/solid structure includes both a porous portion and a solid portion, and wherein the solid portion of the hybrid porous/solid structure covers all but two surfaces of the multiple surfaces of the porous structure, and the porous portion of the hybrid porous/solid structure covers the two surfaces of the porous structure not covered by the solid portion of the hybrid porous/solid structure. In certain embodiments, the two surfaces of the porous structure not covered by the solid portion of the hybrid porous/solid structure are disposed on opposite sides from each other. In certain embodiments, each respective portion of the porous portion of the hybrid porous/solid structure covering the two surfaces of the porous structure not covered by the solid portion of the hybrid porous/solid structure is thinner than the porous structure. In certain embodiments (with two surfaces covered by the porous portion), pores of the porous portion of the hybrid porous/solid structure are smaller than pores of the porous structure. In certain embodiments, the porous structure has a complex geometric shape. In certain embodiments, the porous structure is open on one side with a solid fence in addition to a mold. In certain embodiments, the porous structure includes a printed spacer to create a gap for improved post-processing (cleaning, infiltration, etc.).

In one embodiment, the method includes utilizing three-dimensional (3D) printing to print a single part including both a first porous structure and a second porous structure, wherein the first porous structure is disposed within the second porous structure, and the first porous structure is configured to attenuate acoustic energy. The method also includes infiltrating the single part with filler material. The method further includes curing the single part, wherein the single part has variable porosity configured both to enable the filler material to enter the first porous structure during infiltration and to keep the filler material from leaking out of the first porous structure between the infiltration and curing of the single part. In certain embodiments, the method further includes removing the second porous structure from the first porous structure to obtain the acoustic backing. In certain embodiments, the second porous structure covers every surface of the first porous structure. In certain embodiments, each respective portion of the second porous structure covering each respective surface of the first porous structure is thinner than the first porous structure, and wherein pores of the second porous structure are smaller than pores of the first porous structure. In certain embodiments, the first porous structure has a complex geometric shape.

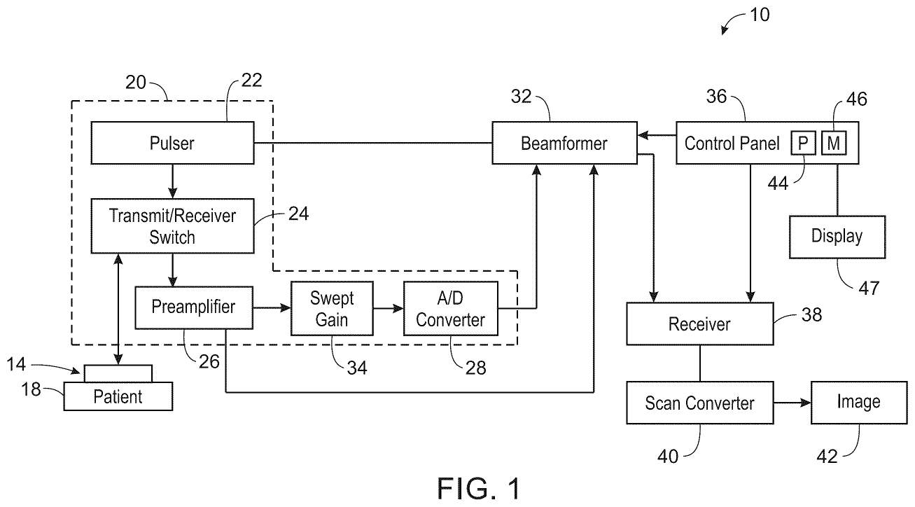

With the preceding in mind, and by way of providing useful context, FIG. 1 depicts a high-level view of components of an ultrasound system 10 that may be employed in accordance with the present approach. It should be noted that while the disclosed additively manufactured acoustic backing is discussed with regard to the ultrasound system 10 and an ultrasound probe, the additively manufactured acoustic backing may be utilized in other types of transducer probes for a variety of applications. The illustrated ultrasound system 10 includes a transducer array 14 having transducer elements suitable for contact with a subject or patient 18 during an imaging procedure. The transducer array 14 may be configured as a two-way transducer capable of transmitting ultrasound waves into and receiving such energy from the subject or patient 18. In such an implementation, in the transmission mode the transducer array elements convert electrical energy into ultrasound waves and transmit it into the patient 18. In reception mode, the transducer array elements convert the ultrasound energy received from the patient 18 (backscattered waves) into electrical signals.

Each transducer element is associated with respective transducer circuitry, which may be provided as one or more application specific integrated circuits (ASICs) 20, which may be present in a probe or probe handle. That is, each transducer element in the array 14 is electrically connected to a respective pulser 22, transmit/receive switch 24, preamplifier 26, swept gain 34, and/or analog to digital (A/D) converter 28 provided as part of or on an ASIC 20. In other implementations, this arrangement may be simplified or otherwise changed. For example, components shown in the circuitry 20 may be provided upstream or downstream of the depicted arrangement, however, the basic functionality depicted will typically still be provided for each transducer element. In the depicted example, the referenced circuit functions are conceptualized as being implemented on a single ASIC 20 (denoted by dashed line), however it may be appreciated that some or all of these functions may be provided on the same or different integrated circuits.

Also depicted in FIG. 1, a variety of other imaging components are provided to enable image formation with the ultrasound system 10. Specifically, the depicted example of an ultrasound system 10 also includes a beam former 32, a control panel 36, a receiver 38, and a scan converter 40 that cooperate with the transducer circuitry to produce an image or series of images 42 that may be stored and/or displayed to an operator or otherwise processed as discussed herein. The transducer array 14 may communicate the ultrasound data to the beam-former via a wired connection or wireless connection (e.g., via a wireless communication unit that is part of the transducer array that communicates over a wi-fi network, utilizing Bluetooth® technique, or some other manner).

A processing component 44 (e.g., a microprocessor or processing circuitry) and a memory 46 of the system 10, such as may be present control panel 36, may be used to execute stored software code, instructions, or routines for processing the acquired ultrasound signals to generate meaningful images and/or motion frames, which may be displayed on a display 47 of the ultrasound system 10. The term “code” or “software code” used herein refers to any instructions or set of instructions that control the ultrasound system 10. The code or software code may exist in a computer-executable form, such as machine code, which is the set of instructions and data directly executed by the processing component 44 of the control panel 36, human-understandable form, such as source code, which may be compiled in order to be executed by the processing component 44 of the control panel 36, or an intermediate form, such as object code, which is produced by a compiler. In some embodiments, the ultrasound system 10 may include a plurality of controllers.

As an example, the memory 46 may store processor-executable software code or instructions (e.g., firmware or software), which are tangibly stored on a non-transitory computer readable medium. Additionally or alternatively, the memory 46 may store data. As an example, the memory 46 may include a volatile memory, such as random access memory (RAM), and/or a nonvolatile memory, such as read-only memory (ROM), flash memory, a hard drive, or any other suitable optical, magnetic, or solid-state storage medium, or a combination thereof. Furthermore, processing component 44 may include multiple microprocessors, one or more “general-purpose” microprocessors, one or more special-purpose microprocessors, and/or one or more application specific integrated circuits (ASICS), or some combination thereof. For example, the processing component 44 may include one or more reduced instruction set (RISC) or complex instruction set (CISC) processors. The processing component 44 may include multiple processors, and/or the memory 46 may include multiple memory devices.

Ultrasound information may be processed by other or different mode-related modules (e.g., B-mode, Color Doppler, power Doppler, M-mode, spectral Doppler anatomical M-mode, strain, strain rate, and the like) to form 2D or 3D data sets of image frames and the like. For example, one or more modules may generate B-mode, color Doppler, power Doppler, M-mode, anatomical M-mode, strain, strain rate, spectral Doppler image frames and combinations thereof, and the like. The image frames are stored and timing information indicating a time at which the image frame was acquired in memory may be recorded with each image frame. The modules may include, for example, a scan conversion module to perform scan conversion operations to convert the image frames from Polar to Cartesian coordinates. A video processor module may be provided that reads the image frames from a memory and displays the image frames in real time while a procedure is being carried out on a patient. A video processor module may store the image frames in an image memory, from which the images are read and displayed. The ultrasound system 10 shown may include a console system, or a portable system, such as a hand-held or laptop-type system.

The ultrasound system 10 may be operable to continuously acquire ultrasound scan data at a frame rate that is suitable for the imaging situation in question. Typical frame rates may range from 20-120 but may be lower or higher. The acquired ultrasound scan data may be displayed on the display 47 at a display-rate that can be the same as the frame rate, or slower or faster. An image buffer may be included for storing processed frames of acquired ultrasound scan data that are not scheduled to be displayed immediately. Preferably, the image buffer is of sufficient capacity to store at least several minutes worth of frames of ultrasound scan data. The frames of ultrasound scan data are stored in a manner to facilitate retrieval thereof according to its order or time of acquisition. The image buffer may be embodied as any known data storage medium.

The display 47 may be any device capable of communicating visual information to a user. For example, the display 47 may include a liquid crystal display, a light emitting diode display, and/or any suitable display or displays. The display 47 can be operable to present ultrasound images and/or any suitable information.

Components of the ultrasound system 10 may be implemented in software, hardware, firmware, and/or the like. The various components of the ultrasound system 10 may be communicatively linked. Components of the ultrasound may be implemented separately and/or integrated in various forms.

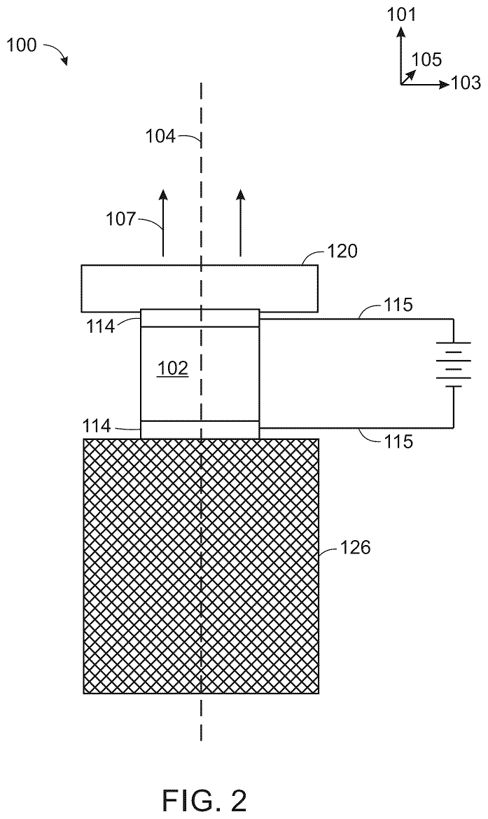

Before further discussion of the approach for manufacturing a modified backing with high acoustic attenuation and high thermal conductivity, a general overview of an acoustic stack for a transducer probe is illustrated in FIG. 2 and described below. In one example, the transducer probe may be an ultrasound probe, although other types of probes demanding absorption of stray acoustic energy and thermal management have been considered.

An ultrasound probe includes one or more active components for generating an ultrasonic signal. An example of an active component, or piezoelectric element 102 of an ultrasound probe is shown in a schematic diagram of an acoustic stack 100 in FIG. 2, with a central axis 104. A set of reference axes are provided, indicating a propagation (e.g., signal propagation) direction 101, an azimuth direction 103, and an elevation direction 105. In other examples, the set of reference axes may represent a z-axis 101, an x-axis 103, and a y-axis 105. The piezoelectric element 102 is shown in FIG. 2 with the central axis 104 parallel with the propagation direction 101.

It will be noted that while the acoustic stack 100 is shown with a propagation direction described as parallel with the z-axis in FIG. 2, other examples may include a propagation direction that is angled relative to the z-axis, depending on a shape of a piezoelectric element array. For example, the ultrasound probe may be curvilinear or phased array, thus generating non-linear beams that are not parallel with the z-axis. Furthermore, while the examples shown and described herein are directed to ultrasound applications, the methods and systems described below may be applicable to a variety of sensor array types.

While a single piezoelectric element is shown in FIG. 2, the ultrasound probe may include a plurality of piezoelectric elements arranged in an array and individually coupled to an electrical energy source by wires. Each electrical circuit formed of one or more piezoelectric elements may be a transducer. In some examples, the transducer may include an array of piezoelectric elements which may be arranged in a variety of patterns, or matrices, including one-dimensional (1D) linear, two-dimensional (2D) square, 2D annular, etc. Each transducer may be electrically insulated from adjacent transducers but may all be coupled to common layers positioned above and below the piezoelectric element, with respect to the propagation direction. The plurality of piezoelectric elements and accompanying layers may be enclosed by an outer housing of the ultrasound probe which may be, for example, a plastic case with a variety of geometries. For example, the outer housing may be a rectangular block, a cylinder, or a shape configured to fit into a user's hand comfortably. As such, components shown in FIG. 2 may be adapted to have geometries and dimensions suitable to fit within the outer housing of the ultrasound probe.

The piezoelectric element 102 may be a block formed of a material, such as lead zirconate titanate, that deforms and vibrates when a voltage is applied by, for example, a transmitter. In some examples, the piezoelectric element 102 may be a single crystal with crystallographic axes, such as PMN-PT (Pb(Mg1/3Nb2/3)O3-PbTiO3). The vibration of the piezoelectric element 102 generates an ultrasonic signal formed of ultrasonic waves that are transmitted out of the ultrasound probe in a direction indicated by arrows 107, e.g., along the propagation direction 101. The piezoelectric element 102 may also receive ultrasonic waves, such as ultrasonic waves reflected from a target object, and convert the ultrasonic waves to a voltage. The voltage may be transmitted to a receiver of the ultrasound imaging system and processed into an image.

Electrodes 114 may be in direct contact with the piezoelectric element 102 to transmit the voltage via wires 115, the voltage converted from ultrasonic waves. The wires 115 may be connected to a circuit board (not shown) to which a plurality of wires from electrodes of the plurality of piezoelectric elements may be fixed. The circuit board may be coupled to a coaxial cable providing electronic communication between the ultrasound probe and the receiver. In one example, the circuit board may be one or more ASICs electrically coupled to the piezoelectric element 102 by an electrical interfacing structure. Together the electrodes 114, the wires 115, and the circuit board may form an electrical circuit or electrical actuator of the piezoelectric element 102. In some examples, the electrical circuit may be a flex circuit, as an alternative to the one or more ASICs.

An acoustic matching layer 120 may be arranged above the piezoelectric element 102, with respect to the propagation direction 101, oriented perpendicular to the central axis 104. The acoustic matching layer 120 may be a material positioned between the piezoelectric element 102 and a target object to be imaged. By arranging the acoustic matching layer 120 in between, the ultrasonic waves may first pass through the acoustic matching layer 120, and emerge from the acoustic matching layer 120 in phase, thereby reducing a likelihood of reflection at the target object. The acoustic matching layer 120 may shorten a pulse length of the ultrasonic signal, which may increase an axial resolution of the signal. Further, in some examples, multiple (e.g., more than one) acoustic matching layer may be included in the acoustic stack 100.

A backing layer 126 may be arranged below the piezoelectric element 102, with respect to the propagation direction 101. In some examples, the backing layer 126 may be a block of material that extends along the azimuth direction 103 (and the elevation direction 105) so that each of the plurality of piezoelectric elements in the ultrasound probe are directly above the backing layer 126, with respect to the propagation direction 101. The backing layer 126 may be configured to absorb ultrasonic waves directed from the piezoelectric element 102 in a direction opposite of the direction indicated by arrows 107. Further, the backing layer 126 may attenuate any stray ultrasonic waves deflected by the transducer and probe in directions other than directions useful for imaging, e.g., directions outside of a range of signal angles that may be transmitted and received by the ultrasound probe based on its specific size and frequency range. A bandwidth of the ultrasonic signal, as well as the axial resolution, may be increased by the backing layer 126.

In one example, as described herein, the backing layer 126 may be fabricated via additive manufacturing. Additive manufacturing of the modified backing may introduce flexibility into its configuration, including a geometry of the modified backing, a porosity, incorporation of internal structures or inclusions, and integration of the modified backing with other components. Furthermore, by controlling such aspects of the modified backing, the modified backing may have thermal management capabilities. For example, the modified backing may be configured to be thermally conductive.

In some examples, the backing layer 126 may be positioned under (e.g., with respect to the z-axis 101) at least one ASIC of the ultrasound probe. In such examples, the backing layer 126 may be formed from a continuous, e.g., undiced, material. Dicing of the backing layer 126 may be challenging due to a thickness of the backing layer 126, which may be greater than other layers of the acoustic stack 100. In other examples, the acoustic stack 100 may also include a dematching layer (not shown in FIG. 2) arranged directly below the piezoelectric element 102 and between the piezoelectric element 102 and the backing layer 126. The dematching layer may be a high acoustic impedance layer that reflects a majority of the ultrasonic signal received by the ultrasound probe out of a front of the ultrasound probe (e.g., along the propagation direction 101), allowing a reflected portion of the ultrasonic signal to be used for imaging.

As described above, a modified backing may be included in an acoustic stack in place of a conventional backing layer. The modified backing may be additively manufactured, and therefore customizable according to a target application while incurring costs during production that are lower than costs of conventional transducer probes. As an example, the modified backing may have a porous matrix that enable random or pseudo-random scattering of acoustic energy and absorption of the scattered acoustic energy. A material and structure of the porous matrix may be nonhomogeneous, which is enabled via additive manufacturing. Further, by forming the modified backing by additive manufacturing, other probe components may be integrated into the modified backing, reducing a number of individual parts of the probe, and increasing an effectiveness of the parts. For example, the modified backing may include at least one structural element, including pore configuration, fillers, and heat conducting structures, that allow the modified backing to provide one or more of a target acoustic attenuation and a target thermal conductivity.

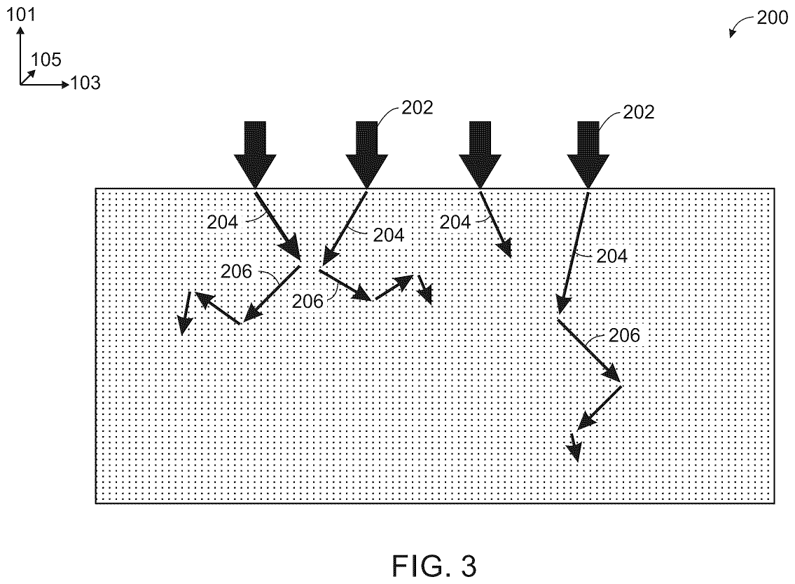

Scattering and absorption, e.g., attenuation, of acoustic energy reflected from a piezoelectric material in an acoustic stack is illustrated in FIG. 3. An example of a modified backing 200 is depicted in FIG. 3, the modified backing 200 being a porous matrix (e.g., porous structure) formed of one or more of aluminum, aluminum nitride, copper, titanium, tungsten, a metal alloy, and stainless steel, and including a filler material filling the porous matrix. A porosity and structure of the modified backing 200 may be random or pseudo-random such that the porosity, and corresponding structure (e.g. crystal structure or molecular structure), may be variable within the modified backing 200, or may be relatively uniform, while maintaining an ability to scatter the acoustic energy in different directions.

As shown in FIG. 3, incident acoustic energy, e.g., acoustic waves, may enter the modified backing 200 as indicated by arrows 202, in a direction opposite of the propagation direction 101. For example, the incident acoustic energy may be reflected into the modified backing 200 from a piezoelectric material arranged in front of the modified backing 200 relative to the propagation direction 101, as depicted in FIG. 3. The incident acoustic energy may have a first intensity upon entering the modified backing 200, as indicated by arrows 204.

The acoustic energy may then interact with the modified backing 200 and be redirected to travel in a different direction. For example, the acoustic energy may be reflected off of the structure of the matrix, such as at a pore. Further, vibration of the material of the modified backing 200 may be induced by the incident acoustic energy and may interfere destructively with the acoustic energy travelling therethrough. The intensity of the acoustic energy may decrease as it is scattered and absorbed by the porous matrix and filler, as indicated by arrows 206.

The acoustic energy may continue to be scattered and decreased in intensity through the modified backing 200 until the acoustic energy is fully dissipated. A number of reflections of the acoustic energy within the modified backing 200 that is demanded for complete absorption of the acoustic energy may vary, as shown in FIG. 3. The acoustic energy may be bounced in a variable manner within the modified backing 200 and dampened concurrently, thereby minimizing escape of the acoustic energy out from the modified backing 200.

Attenuative properties of the modified backing may be optimized by adjustment of various parameters of the modified backing, which may be enabled via additive manufacturing of the modified backing layer. For example, the modified backing may be formed having a near-net shape, thereby minimizing application of finishing processes, such as machining or grinding, to achieve a final, desired geometry of the backing layer. When formed with the near-net shape, the modified backing may be produced with a geometry that is very close to a desired final, or net shape of the modified backing. In some instances, additive manufacturing of the modified backing allows machining or grinding of the modified backing to be precluded. As one example, a shape of the modified backing may be selected, e.g., by an operator, during fabrication of the modified backing such that the modified backing is additively manufactured with a desired geometry.

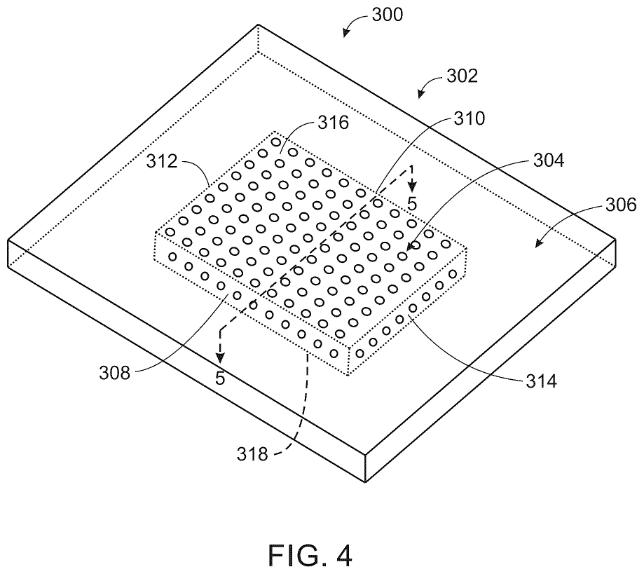

FIG. 4 is a perspective view of an additively manufactured acoustic backing with a built in (e.g., integrated) infiltration mold 300. The acoustic backing with a built in infiltration mold 300 is additively manufactured as a single part 302. The single part 302 is additively manufactured (e.g. 3D printed, for example, utilizing via direct metal laser sintering). The single part 302 is printed to have multi-parameters. For example, a portion of the single part 302 includes an acoustic attenuation parameter set (and some porosity). A further portion of the single part 302 includes a parameter set having a high density. In certain embodiments, the further portion of the single part 302 includes some porosity.

In particular, the single part 302 includes a porous structure 304 (porous matrix) configured to attenuate acoustic energy. In certain embodiments, the porous structure 304 also has good thermal conductivity. The porous structure 304 may be formed of one or more of aluminum, aluminum nitride, copper, titanium, tungsten, a metal alloy, and stainless steel, and may include a filler material (e.g., resin such as lossy epoxy) filling the porous structure 304. A porosity and structure of the porous structure 304 may be random or pseudo-random such that the porosity, and corresponding structure (e.g. crystal structure or molecular structure), may be variable within the porous structure 304, or may be relatively uniform, while maintaining an ability to scatter the acoustic energy in different directions.

The single part 302 also includes a mold 306 (e.g., built in infiltration mold). The porous structure 304 is disposed within the mold 306. In certain embodiments, the porous structure 304 is enclosed within the mold 306. In certain embodiments, the entirety of the mold 306 is solid to keep filler material from leaking out of the porous structure 304 during infiltration (and between infiltration and curing). In certain embodiments, one or more portions of the mold 306 may be porous to enable filler material to enter the porous structure 304 but to keep the filler material from leaking out of the porous structure 304 during infiltration (and between infiltration and curing). In certain embodiments, where one or more portions of the mold 306 are porous, the porous portions of the mold 306 are smaller than the pores of the porous structure 304. In certain embodiments, where one or more portions of the mold 306 are porous, the one or porous portions are thinner than the porous structure 304. In certain embodiments, the mold 306 and the porous structure 304 are made of the same material. In certain embodiments, the mold 306 is removed (e.g., machined off) prior to obtain the acoustic backing utilized in the transducer probe. In certain embodiments, the mold 306 is kept as part of the acoustic backing utilized in the transducer probe. In certain embodiments, the mold 306 also includes a built-in fence to create a reservoir to retain filler material during the cure process to ensure adequate filler material is available to fill pores. This built-in fence can also include a channel around the perimeter of the mold and porous material to allow filler material to enter and air to exit the backing. In certain embodiments, the porous structure 304 also includes spacers to create an air gap between the mold 306 and porous structure 304. This air gap improves post-processing (cleaning, infiltration, etc.).

As depicted in FIG. 4, the porous structure 304 is a rectangular prism. However, the shape of the porous structure 304 may vary. In certain embodiments, the porous structure 304 may have a complex geometric shape. The porous structure 304 includes multiple surfaces or sides. As depicted, the surfaces or sides of the porous structure 304 are flat. In certain embodiments, one or more surfaces or sides (or portions of the one or more surfaces or sides) of the porous structure 304 may be curved. In certain embodiments, one or more surfaces or sides (or portions of the one or more surfaces or sides) of the porous structure 304 may be a combination of curved or flat. As depicted, the porous structure 304 has a first surface 308 (e.g., first side) and a second surface 310 (e.g., second side) disposed opposite the first surface 308. The porous structure 304 also includes a third surface 312 (e.g., third side) and a fourth surface 314 (e.g., fourth side) disposed opposite the third surface 312. The porous structure 304 further incudes a fifth surface 316 (e.g., fifth side) and a sixth surface 318 (e.g., sixth side) disposed opposite the fifth surface 316. Both the fifth surface 316 and the sixth surface 318 extend between the first surface 308, the second surface 310, the third surface 312, and the fourth surface 314.

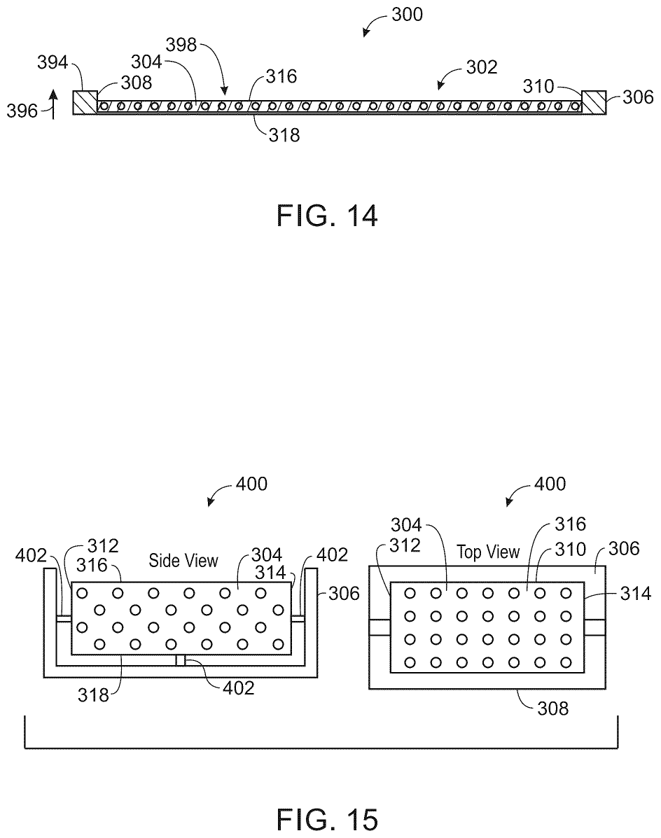

As depicted in FIG. 4, the mold 306 surrounds the porous structure 304. The mold 306 has a rectangular shape. The shape of the mold 306 may vary. As depicted, the mold 306 contacts at least the first surface 308, the second surface 310, the third surface 312, and the fourth surface 314 of the porous structure 304. In certain embodiments, the mold 306 also contacts the fifth surface 316 and/or the sixth surface 318 of the porous structure 304. In certain embodiments, the mold 306 also includes an extended fence to create a reservoir (e.g., as depicted in FIG. 14) and can include a channel as well.

As described in greater detail below, there are multiple methods for manufacturing an additively manufacturing acoustic backing that enables filler material to enter the porous structure through one or more sides of the single part 302. In addition, geometry (wall thickness, gates, vents, etc.) can modified in parallel with parameters to infiltrate the porous structure 304 during vacuum infiltration but hold the liquid resin in place using capillary forces prior to curing. In certain embodiments, the mold 306 can be utilized to retain un-sintered powder (e.g., un-sintered metallic powder) within the porous structure 304 during vacuum infiltration to improve thermal conductivity or acoustic attenuation. The techniques described herein may be utilized with the geometries of the acoustic backing and the techniques described in U.S. patent application Ser. No. 18/309,344, entitled “METHODS AND SYSTEMS FOR A MODIFIED BACKING”, filed Apr. 28, 2023, which is herein incorporated by reference in its entirety.

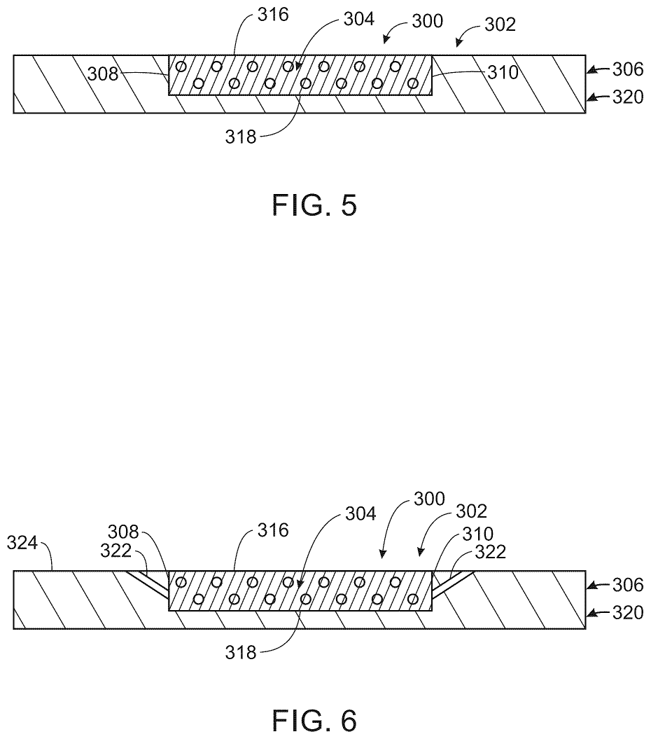

FIG. 5 is cross-sectional view of an additively manufactured acoustic backing with a built in (e.g., integrated) infiltration mold 300 (e.g., with the mold 306 having one side open), taken along line 5-5 in FIG. 4. As noted above, the acoustic backing with a built in infiltration mold 300 is additively manufactured as a single part 302. The single part 302 is additively manufactured (e.g. 3D printed, for example, utilizing via direct metal laser sintering). The single part 302 is printed to have multi-parameters. For example, a portion of the single part 302 includes an acoustic attenuation parameter set (and some porosity). A further portion of the single part 302 includes a parameter set having a high density.

In particular, the single part 302 includes the porous structure 304 (porous matrix) configured to attenuate acoustic energy. In certain embodiments, the porous structure 304 also has good thermal conductivity. The porous structure 304 may be formed of one or more of aluminum, aluminum nitride, copper, titanium, tungsten, a metal alloy, and stainless steel, and may include a filler material (e.g., resin such as lossy epoxy) filling the porous structure 304. A porosity and structure of the porous structure 304 may be random or pseudo-random such that the porosity, and corresponding structure (e.g. crystal structure or molecular structure), may be variable within the porous structure 304, or may be relatively uniform, while maintaining an ability to scatter the acoustic energy in different directions.

The single part 302 also includes the mold 306 (e.g., built in infiltration mold). The porous structure 304 is disposed within the mold 306. The entirety of the mold 306 is a solid structure 320 to keep filler material from leaking out of the porous structure 304 during infiltration (and between infiltration and curing). The solid structure 320 contacts and covers the first surface 308, the second surface 310, the third surface 312 (see FIG. 4), the fourth surface 314 (see FIG. 4), and the sixth surface 318. The solid structure 320 does not cover the fifth surface 316 of the porous structure 304, thus, leaving the fifth surface 316 exposed or open to the environment (e.g., during infiltration). The embodiment depicted in FIG. 5 requires that the orientation of the single part 302 be fixed during infiltration (i.e., with the fifth surface 316 of the porous structure 304 facing up).

In certain embodiments, the mold 306 and the porous structure 304 are made of the same material. In certain embodiments, the mold 306 is removed (e.g., machined off) prior to obtain the acoustic backing utilized in the transducer probe. In certain embodiments, the mold 306 is kept as part of the acoustic backing utilized in the transducer probe.

FIG. 6 is cross-sectional view of an additively manufactured acoustic backing with a built in (e.g., integrated) infiltration mold 300 (e.g., with the mold 306 having one side open and internal passages), taken along line 5-5 in FIG. 4. As noted above, the acoustic backing with a built in infiltration mold 300 is additively manufactured as a single part 302. The single part 302 is additively manufactured (e.g. 3D printed, for example, utilizing via direct metal laser sintering). The single part 302 is printed to have multi-parameters. For example, a portion of the single part 302 includes an acoustic attenuation parameter set (and some porosity). A further portion of the single part 302 includes a parameter set having a high density.

In particular, the single part 302 includes the porous structure 304 (porous matrix) configured to attenuate acoustic energy. In certain embodiments, the porous structure 304 also has good thermal conductivity. The porous structure 304 may be formed of one or more of aluminum, aluminum nitride, copper, titanium, tungsten, a metal alloy, and stainless steel, and may include a filler material (e.g., resin such as lossy epoxy) filling the porous structure 304. A porosity and structure of the porous structure 304 may be random or pseudo-random such that the porosity, and corresponding structure (e.g. crystal structure or molecular structure), may be variable within the porous structure 304, or may be relatively uniform, while maintaining an ability to scatter the acoustic energy in different directions.

The single part 302 also includes the mold 306 (e.g., built in infiltration mold). The porous structure 304 is disposed within the mold 306. The entirety of the mold 306 is a solid structure 320 to keep filler material from leaking out of the porous structure 304 during infiltration (and between infiltration and curing). The solid structure 320 contacts and covers the first surface 308, the second surface 310, the third surface 312 (see FIG. 4), the fourth surface 314 (see FIG. 4), and the sixth surface 318. The solid structure 320 does not cover the fifth surface 316 of the porous structure 304, thus, leaving the fifth surface 316 exposed or open to the environment (e.g., during infiltration). The embodiment depicted in FIG. 6 requires that the orientation of the single part 302 be fixed during infiltration (i.e., with the fifth surface 316 of the porous structure 304 facing up).

In addition, the solid structure 320 includes one or more passages 322 extending from an exposed surface 324 (e.g., top surface) of the solid structure 320 to one or more surfaces of the porous structure 304. The one or more passages 322 are configured to enable the resin (e.g., lossy epoxy) and/or an un-sintered metallic powder (e.g., the same or different from any un-sintered metallic powder already present in the 304 porous structure 304 after printing) to enter the porous structure via the one or more surfaces during infiltration. The number of passages 322 may vary. For example, the solid structure 320 may include 1, 2, 3, 4, 5, or more passages 322. The number of surfaces and/or which surfaces of the porous structure 304 coupled to the passages 322 may vary. In certain embodiments, more than one passage 322 may be coupled to a respective surface of the porous structure 304. As depicted, the solid structure 320 includes two passages 322 with a single respective passage 322 coupled to each of the first surface 308 and the second surface 310 of the porous structure 304.

In certain embodiments, the mold 306 and the porous structure 304 are made of the same material. In certain embodiments, the mold 306 is removed (e.g., machined off) prior to obtain the acoustic backing utilized in the transducer probe. In certain embodiments, the mold 306 is kept as part of the acoustic backing utilized in the transducer probe.

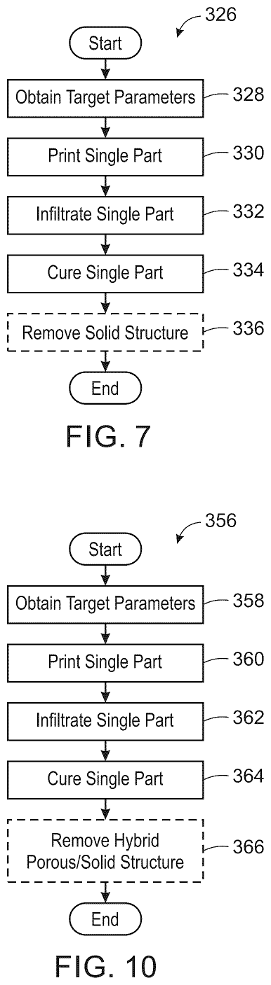

FIG. 7 is a flow chart of a method 326 for manufacturing the acoustic backing with a built in (e.g., integrated) infiltration mold 300 (e.g., with the mold 306 having one side open) as described in FIGS. 5 and 6. The steps 328 and 330 of the method 326 may be executed by a 3D printer configure to receive input from an operator and having executable instructions stored on a memory of the controller of the 3D printer.

The method 326 includes obtaining target parameters for the acoustic backing (e.g., multi-parameter backing) with a built in (e.g., integrated) infiltration mold 300 (e.g., with mold 306 having one side open) (block 328). The target parameters may be stored at the memory of the controller by the operator. For example, the target parameters may include a type of probe in which the modified backing is to be incorporated, a target acoustic attenuation (e.g., for the porous structure 304), a target thermal conductivity (e.g., for the porous structure 304), and one or more materials from which the porous structure 304 and the solid structure 320 are to be formed. The target parameters may include a porosity, pore structure, and distribution of pores of a matrix (e.g., porous structure 304) of the modified backing, variations in the pores to form a gradient structure in the porous structure 304, and a density of the solid structure 320. In certain embodiments, the target parameters may include a location of one or more passages 322 in the solid structure 320. In addition, the target parameters may include manufacturing conditions, such as print parameters, including laser power, printing speed, print directions, print angle, print hatching, print orientation, and so forth.

The method 326 also includes printing the single part 302 including both the porous structure 304 and the solid structure 320 (i.e., the mold 306) (block 330). The porous structure 304 is disposed within the solid structure 320, and the porous structure 304 is configured to attenuate acoustic energy. The single part 302 is printed according to the obtained target parameters.

The method 326 further includes infiltrating the single part 302 with resin or liquid filler (such as a lossy epoxy) (block 332). An industrial type infiltration (e.g., vacuum infiltration) system may be utilized for performing infiltration on the single part 302.

The method 326 even further includes curing the single part (block 334). The single part 302 is configured both to enable both filler material to enter the porous structure 304 during infiltration and to keep filler material from leaking out of the porous structure 304 during infiltration as well as between the infiltration and curing of the single part 302. The curing of the single part 302 may occur using an ultraviolet light source (e.g., in a curing station). In certain embodiments, the method 326 still further includes removing the solid structure 320 (i.e., the mold 306) from the porous structure 304 to obtain the acoustic backing (i.e., the porous structure 304) (block 336).

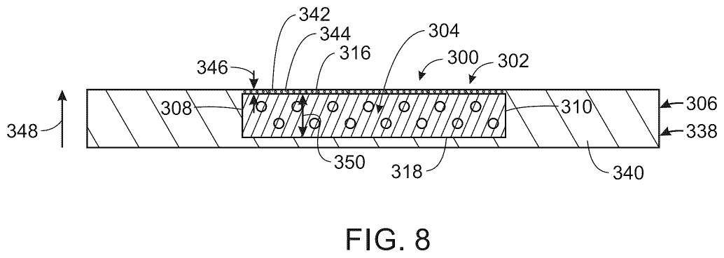

FIG. 8 is cross-sectional view of an additively manufactured acoustic backing with a built in (e.g., integrated) infiltration mold (e.g., with the mold 306 having one side porous), taken along line 5-5 in FIG. 4. As noted above, the acoustic backing with a built in infiltration mold 300 is additively manufactured as a single part 302. The single part 302 is additively manufactured (e.g. 3D printed, for example, utilizing via direct metal laser sintering). The single part 302 is printed to have multi-parameters. For example, a portion of the single part 302 includes an acoustic attenuation parameter set (and some porosity). A further portion of the single part 302 includes a parameter set having a high density and porosity.

In particular, the single part 302 includes the porous structure 304 (porous matrix) configured to attenuate acoustic energy. In certain embodiments, the porous structure 304 also has good thermal conductivity. The porous structure 304 may be formed of one or more of aluminum, aluminum nitride, copper, titanium, tungsten, a metal alloy, and stainless steel, and may include a filler material (e.g., resin such as lossy epoxy) filling the porous structure 304. A porosity and structure of the porous structure 304 may be random or pseudo-random such that the porosity, and corresponding structure (e.g. crystal structure or molecular structure), may be variable within the porous structure 304, or may be relatively uniform, while maintaining an ability to scatter the acoustic energy in different directions.

The single part 302 also includes the mold 306 (e.g., built in infiltration mold). The porous structure 304 is disposed within the mold 306. The mold 306 is a hybrid porous/solid structure 338. In particular, the hybrid porous/solid structure 338 includes a solid portion 340 and a porous portion 342. The solid portion 340 of the mold 306 keeps resin from leaking out of the porous structure 304 during infiltration (and between infiltration and curing). The solid structure 320 contacts and covers the first surface 308, the second surface 310, the third surface 312 (see FIG. 4), the fourth surface 314 (see FIG. 4), and the sixth surface 318. The solid structure 320 does not cover the fifth surface 316 of the porous structure 304. The porous portion 342 of the mold 306 both enables resin to infiltrate the porous structure 304 during infiltration and keeps resin from leaking out of the porous structure 304 during infiltration (and between infiltration and curing). The porous portion 342 is a thin porous wall 344 that covers the fifth surface 316 of the porous structure 304. Besides the thin porous wall 344 enabling resin to be pulled into the porous structure 304 during infiltration, the thin porous wall 344 retains the resin in the porous structure 304 due to capillary force.

The thin porous wall 344 has a length 346 (e.g., height) in a direction 348 (e.g., with direction 348 oriented from the sixth surface 318 to the fifth surface 316 or vice versa). The porous structure 304 has a length 350 (e.g., height) in the direction 348. The length 346 of the thin porous wall 344 is less than the length 350 of the porous structure 304. Thus, the thin porous wall 344 is thinner than the porous structure 304. In addition, the pores of the thin porous wall 344 (and of the porous portion 342) are smaller than the pores of the porous structure 304.

The embodiment depicted in FIG. 8 requires that the orientation of the single part 302 be fixed during infiltration (i.e., with the fifth surface 316 of the porous structure 304 facing up). The embodiment depicted in FIG. 8 retains un-sintered metallic powder within the porous structure 304 to improve both thermal conductivity and acoustic attenuation.

In certain embodiments, the mold 306 and the porous structure 304 are made of the same material. In certain embodiments, the mold 306 is removed (e.g., machined off) prior to obtain the acoustic backing utilized in the transducer probe. In certain embodiments, the mold 306 is kept as part of the acoustic backing utilized in the transducer probe.

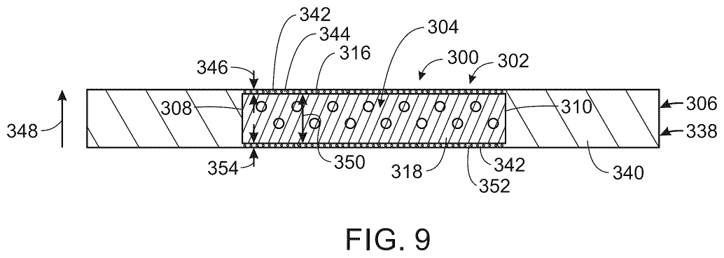

FIG. 9 is cross-sectional view of an additively manufactured acoustic backing with a built in (e.g., integrated) infiltration mold 300 (e.g., with the mold 306 having two sides porous), taken along line 5-5 in FIG. 4. As noted above, the acoustic backing with a built in infiltration mold 300 is additively manufactured as a single part 302. The single part 302 is additively manufactured (e.g. 3D printed, for example, utilizing via direct metal laser sintering). The single part 302 is printed to have multi-parameters. For example, a portion of the single part 302 includes an acoustic attenuation parameter set (and some porosity). A further portion of the single part 302 includes a parameter set having a high density and porosity.

In particular, the single part 302 includes the porous structure 304 (porous matrix) configured to attenuate acoustic energy. In certain embodiments, the porous structure 304 also has good thermal conductivity. The porous structure 304 may be formed of one or more of aluminum, aluminum nitride, copper, titanium, tungsten, a metal alloy, and stainless steel, and may include a filler material (e.g., resin such as lossy epoxy) filling the porous structure 304. A porosity and structure of the porous structure 304 may be random or pseudo-random such that the porosity, and corresponding structure (e.g. crystal structure or molecular structure), may be variable within the porous structure 304, or may be relatively uniform, while maintaining an ability to scatter the acoustic energy in different directions.

The single part 302 also includes the mold 306 (e.g., built in infiltration mold). The porous structure 304 is disposed within the mold 306. The mold 306 is a hybrid porous/solid structure 338. In particular, the hybrid porous/solid structure 338 includes a solid portion 340 and a porous portion 342. The solid portion 340 of the mold 306 keeps resin from leaking out of the porous structure 304 during infiltration (and between infiltration and curing). The solid structure 320 contacts and covers the first surface 308, the second surface 310, the third surface 312 (see FIG. 4), and the fourth surface 314 (see FIG. 4). The solid structure 320 does not cover both the fifth surface 316 and the sixth surface 318 of the porous structure 304. The porous portion 342 of the mold 306 both enables resin to infiltrate the porous structure 304 during infiltration and keeps resin from leaking out of the porous structure 304 during infiltration (and between infiltration and curing). The porous portion 342 is a thin porous wall 344 that covers the fifth surface 316 of the porous structure 304 and a thin porous wall 352 that covers the sixth surface 318 of the porous structure 304. Besides the thin porous walls 344, 352 enabling resin to be pulled into the porous structure 304 during infiltration, the thin porous walls 344, 352 retain the resin in the porous structure 304 due to capillary force.

The thin porous wall 344 has a length 346 (e.g., height) in a direction 348 (e.g., with direction 348 oriented from the sixth surface 318 to the fifth surface 316 or vice versa). The thin porous wall 352 has a length 354 (e.g., height) in the direction 348. In certain embodiments, the lengths 346, 354 of the thin porous walls 344, 352 are the same. In certain embodiments, the lengths 346, 354 of the thin porous walls 344, 352 are different. The porous structure 304 has a length 350 (e.g., height) in the direction 348. The lengths 346, 354 of the thin porous walls 344, 352 are both less than the length 350 of the porous structure 304. Thus, the thin porous walls 344 are each thinner than the porous structure 304. In addition, the pores of the thin porous walls 344, 352 (and of the porous portion 342) are smaller than the pores of the porous structure 304.

The embodiment depicted in FIG. 9 is less dependent on the orientation and gravity when performing infiltration on the single part 302. Indeed, due to symmetry of the single part 302, it makes the single part 302 a poka-yoke part when loading for infiltration. The embodiment depicted in FIG. 9 retains un-sintered metallic powder within the porous structure 304 to improve both thermal conductivity and acoustic attenuation.

In certain embodiments, the mold 306 and the porous structure 304 are made of the same material. In certain embodiments, the mold 306 is removed (e.g., machined off) prior to obtain the acoustic backing utilized in the transducer probe. In certain embodiments, the mold 306 is kept as part of the acoustic backing utilized in the transducer probe.

FIG. 10 is a flow chart of a method 356 for manufacturing an acoustic backing with a built in (e.g., integrated) infiltration mold (e.g., with the mold 306 having one or two porous sides) as described in FIGS. 8 and 9. The steps 358 and 360 of the method 356 may be executed by a 3D printer configure to receive input from an operator and having executable instructions stored on a memory of the controller of the 3D printer.

The method 356 includes obtaining target parameters for the acoustic backing (e.g., multi-parameter backing) with a built in (e.g., integrated) infiltration mold 300 (e.g., with mold 306 having one or two porous sides) (block 358). The target parameters may be stored at the memory of the controller by the operator. For example, the target parameters may include a type of probe in which the modified backing is to be incorporated, a target acoustic attenuation (e.g., for the porous structure 304), a target thermal conductivity (e.g., for the porous structure 304), and one or more materials from which the porous structure 304 and the solid structure 320 are to be formed. The target parameters may include a porosity, pore structure, and distribution of pores of a matrix (e.g., porous structure 304) of the modified backing, variations in the pores to form a gradient structure in the porous structure 304, a density of the solid portion 340 as well as a porosity, pore structure, and distribution of pores of the porous portion 342. In addition, the target parameters may include manufacturing conditions, such as print parameters, including laser power, printing speed, print directions, print angle, print hatching, print orientation, and so forth.

The method 356 also includes printing the single part 302 including both the porous structure 304 and the hybrid porous/solid structure 338 (i.e., the mold 306) (block 360). The porous structure 304 is enclosed within the hybrid porous/solid structure 338, and the porous structure 304 is configured to attenuate acoustic energy. The single part 302 is printed according to the obtained target parameters.

The method 356 further includes infiltrating the single part 302 with resin or liquid filler (such as a lossy epoxy) (block 362). An industrial type infiltration (e.g., vacuum infiltration) system may be utilized for performing infiltration on the single part 302.

The method 356 even further includes curing the single part (block 364). The single part 302 is configured both to enable both resin to enter the porous structure 304 during infiltration and to keep resin from leaking out of the porous structure 304 during infiltration as well as between the infiltration and curing of the single part 302. The curing of the single part 302 may occur using an ultraviolet light source (e.g., in a curing station). In certain embodiments, the method 356 still further includes removing the hybrid porous/solid structure 338 (i.e., the mold 306) from the porous structure 304 to obtain the acoustic backing (i.e., the porous structure 304)(block 366).

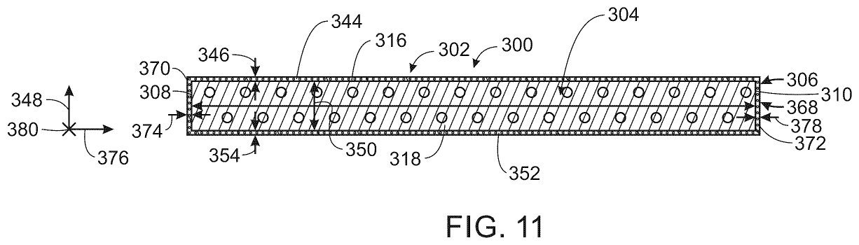

FIG. 11 is cross-sectional view of an additively manufactured acoustic backing with a built in (e.g., integrated) infiltration mold 300 (e.g., with the mold 306 having all sides porous), taken along line 5-5 in FIG. 4. As noted above, the acoustic backing with a built in infiltration mold 300 is additively manufactured as a single part 302. The single part 302 is additively manufactured (e.g. 3D printed, for example, utilizing via direct metal laser sintering). The single part 302 is printed to have multi-parameters. For example, a portion of the single part 302 includes an acoustic attenuation parameter set (and some porosity). A further portion of the single part 302 includes a parameter set having a high density and porosity.

In particular, the single part 302 includes a first porous structure 304 (porous matrix) configured to attenuate acoustic energy. In certain embodiments, the first porous structure 304 also has good thermal conductivity. The first porous structure 304 may be formed of one or more of aluminum, aluminum nitride, copper, titanium, tungsten, a metal alloy, and stainless steel, and may include a filler material (e.g., resin such as lossy epoxy) filling the first porous structure 304. A porosity and structure of the first porous structure 304 may be random or pseudo-random such that the porosity, and corresponding structure (e.g. crystal structure or molecular structure), may be variable within the first porous structure 304, or may be relatively uniform, while maintaining an ability to scatter the acoustic energy in different directions.

The single part 302 also includes the mold 306 (e.g., built in infiltration mold). The first porous structure 304 is disposed within the mold 306. The mold 306 is a second porous structure 368. The second porous structure 368 contacts and covers all surfaces of the first porous structure 304 (i.e., the first surface 308, the second surface 310, the third surface 312 (see FIG. 4), the fourth surface 314 (see FIG. 4), the fifth surface 316, and the sixth surface 318). The second porous structure 368 of the mold 306 both enables resin to infiltrate the first porous structure 304 during infiltration and keeps resin from leaking out of the first porous structure 304 during infiltration (and between infiltration and curing). The second porous structure 368 includes a thin porous wall 370 that covers the first surface 308, a thin porous wall 372 that covers the second surface 310, a thin porous wall (not shown) that covers the third surface 312 (see FIG. 4), a thin porous wall (not shown) that covers the fourth surface 314 (see FIG. 4), the thin porous wall 344 that covers the fifth surface 316 of the porous structure 304, and the thin porous wall 352 that covers the sixth surface 318 of the porous structure 304. Besides the second porous structure 368 enabling resin to be pulled into the first porous structure 304 during infiltration, the second porous structure 368 retains the resin in the first porous structure 304 due to capillary force.

The thin porous wall 344 has a length 346 (e.g., height) in a direction 348 (e.g., with direction 348 oriented from the sixth surface 318 to the fifth surface 316 or vice versa). The thin porous wall 352 has a length 354 (e.g., height) in the direction 348. The thin porous wall 370 has a length 374 (e.g., width) in a direction 376 (e.g., with direction 376 oriented from the first surface 308 to the second surface 310 or vice versa). The thin porous wall 372 has a length 378 (e.g., width) in the direction 376. The thin porous walls covering the third surface 312, respectively, each have a length (e.g., width) in a direction 380 (e.g., with direction 380 oriented from the third surface 312 to the fourth surface 314 or vice versa). In certain embodiments, the lengths of all of the thin porous walls are the same. In certain embodiments, the lengths of one or more of the thin porous walls are different from the other thin porous walls. The porous structure 304 has a length 350 (e.g., height) in the direction 348. The respective length of each thin porous wall of the second porous structure 368 is less than each respective length of the first porous structure 304 in the directions 348, 376, and 380. Thus, each thin porous wall of the second porous structure 368 is thinner than the first porous structure 304. In addition, the pores of the second porous structure 368 are smaller than the pores of the first porous structure 304.

The embodiment depicted in FIG. 11 is less dependent on the orientation and gravity when performing infiltration on the single part 302. Indeed, due to symmetry of the single part 302, it makes the single part 302 a poka-yoke part when loading for infiltration. The embodiment depicted in FIG. 11 retains un-sintered metallic powder within the first porous structure 304 to improve both thermal conductivity and acoustic attenuation.

In certain embodiments, the mold 306 and the first porous structure 304 are made of the same material. In certain embodiments, the mold 306 is removed (e.g., machined off) prior to obtain the acoustic backing utilized in the transducer probe. In certain embodiments, the mold 306 is kept as part of the acoustic backing utilized in the transducer probe.

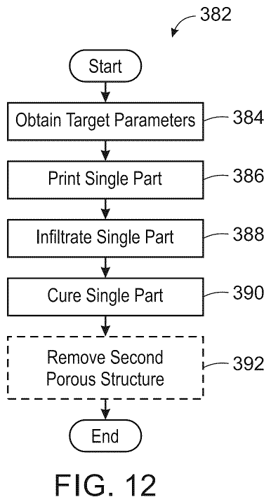

FIG. 12 is a flow chart of a method 382 for manufacturing an acoustic backing with a built in (e.g., integrated) infiltration mold 300 (e.g., with the mold 306 having all sides porous) as described in FIG. 11. The steps 384 and 386 of the method 356 may be executed by a 3D printer configure to receive input from an operator and having executable instructions stored on a memory of the controller of the 3D printer.

The method 382 includes obtaining target parameters for the acoustic backing (e.g., multi-parameter backing) with a built in (e.g., integrated) infiltration mold 300 (e.g., with mold 306 having all sides porous) (block 384). The target parameters may be stored at the memory of the controller by the operator. For example, the target parameters may include a type of probe in which the modified backing is to be incorporated, a target acoustic attenuation (e.g., for the first porous structure 304), a target thermal conductivity (e.g., for the porous structure 304), and one or more materials from which the porous structure 304 and the solid structure 320 are to be formed. The target parameters may include a porosity, pore structure, and distribution of pores of a matrix (e.g., the first porous structure 304) of the modified backing, and variations in the pores to form a gradient structure in the first porous structure 304 as well as a porosity, pore structure, and distribution of pores of the second porous structure 368. In addition, the target parameters may include manufacturing conditions, such as print parameters, including laser power, printing speed, print directions, print angle, print hatching, print orientation, and so forth.

The method 382 also includes printing the single part 302 including both the first porous structure 304 and the second porous structure 368 (i.e., the mold 306) (block 386). The porous structure 304 is enclosed within the second porous structure 368, and the first porous structure 304 is configured to attenuate acoustic energy. The single part 302 is printed according to the obtained target parameters.

The method 382 further includes infiltrating the single part 302 with resin or liquid filler (such as a lossy epoxy) (block 388). An industrial type infiltration (e.g., vacuum infiltration) system may be utilized for performing infiltration on the single part 302.

The method 382 even further includes curing the single part (block 390). The single part 302 is configured both to enable both resin to enter the first porous structure 304 during infiltration and to keep resin from leaking out of the first porous structure 304 during infiltration as well as between the infiltration and curing of the single part 302. The curing of the single part 302 may occur using an ultraviolet light source (e.g., in a curing station). In certain embodiments, the method 382 still further includes removing the second porous structure 368 (i.e., the mold 306) from the first porous structure 304 to obtain the acoustic backing (i.e., the first porous structure 304) (block 392).

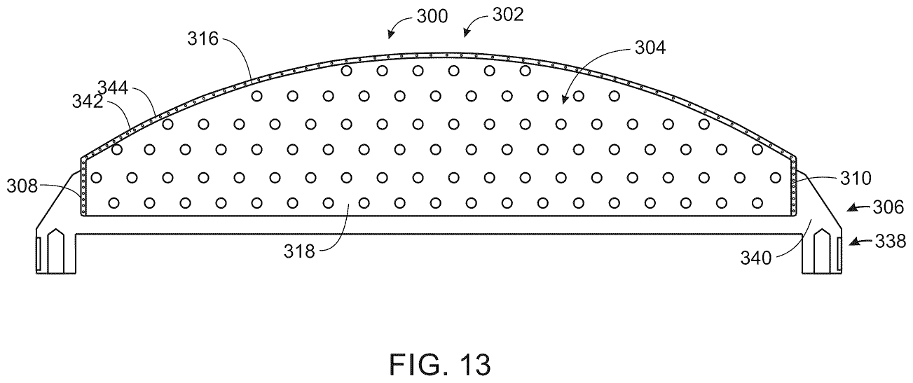

FIG. 13 is cross-sectional view of an additively manufactured acoustic backing with a built in (e.g., integrated) infiltration mold 300 (e.g., with the mold 306 having one side porous), taken along line 5-5 in FIG. 4. The single part 302 in FIG. 13 is similar to the single part 302 described in FIG. 8 except the porous structure 304 has a complex geometric shape. For example, the fifth surface 316 of the porous structure 304 is curved in FIG. 13. Thus, thin porous wall 344 of the porous portion 342 of the hybrid porous/solid structure 338 is also curved. The single part 302 in FIG. 8 functions as described in FIG. 8 during manufacture (e.g., infiltration and curing). The complex geometric shape of the porous structure 304 may differ from that shown in FIG. 13. In addition, the shape and structure of the mold 306 may also differ from that shown in FIG. 13. The mold 306 may also have a complex geometric shape. The porous structure 304 may have a complex geometric shape in any of the embodiments or techniques described above. The single part 302 may be printed with a complex geometry having multiple bodies (both porous and solid using any print parameter set) or lattice structures.

FIG. 14 is cross-sectional view of an additively manufactured acoustic backing with a built in (e.g., integrated) infiltration mold 300 (e.g., with mold 306 having one side open) and a built-in fence to retain filler material and create a reservoir. As above, the additively manufactured acoustic backing with the built in infiltration mold 300 is additively manufactured as the single part 302. The mold 306 forms a built-in fence 394 that runs along and contacts all four surfaces of the porous structure 304 (e.g., the first surface 308 and the second surface 310 as depicted in FIG. 14 and the third surface 312 and the fourth surface 314 as depicted in FIG. 4.). The mold 306 is open above the fifth surface 316 of the porous structure 304. The built-in fence 394 also runs along and contacts the sixth surface 318 of the porous structure 304. The portions of the built-in fence 394 adjacent the surfaces 308, 310, 312, and 314 extends in a vertical direction 396 beyond the fifth surface 316 of the porous structure 304 to retain filler material and create a reservoir 398. In certain embodiments, a channel or an air gap around the perimeter of the porous material 304 (e.g., adjacent the first surface 308 and the second surface 310 as depicted in FIG. 14 and the third surface 312 and the fourth surface 314 as depicted in FIG. 4) may be included to allow filler material to enter and air to leave. The reservoir 398 retains excess filler material and channels permit filler material to enter and air to exit. In certain embodiments, the reservoir 398 can also include a hole that acts as a spill way to allow the evacuation of excess filler material after the acoustic backing material is infiltrated. The hole can be plugged during filling.

FIG. 15 is a cross-sectional view and a top view of an additively manufactured acoustic backing 400. The additively manufactured acoustic backing 400 includes the porous structure 304 as described above in FIG. 4. The porous material 304 is additively manufactured (e.g., printed) with spacers 402. The number of spacers 402 and location of the spaces 402 may vary. In certain embodiments, the porous material 304 and spacers 402 are printed along with the mold 306 as a single part. In certain embodiments, only the porous material 304 and the spacers 402 may be printed as a single part and then disposed within a secondary mold. As depicted, spacers 402 are located between the mold 306 and the third surface 312, the fourth surface 314, and the sixth surface 318 of the porous structure 304. However, the spacers 402 can be present on any of surfaces of the porous structure 304. As depicted, the fifth surface 316 of the porous structure 304 is exposed. The mold 306 is used for retaining filler material and allowing air to escape but allows enough of a gap for easier post-processing (cleaning, infiltration, etc.). This embodiment can be used with multiple geometries for the porous structure 304 and/or the mold 306.

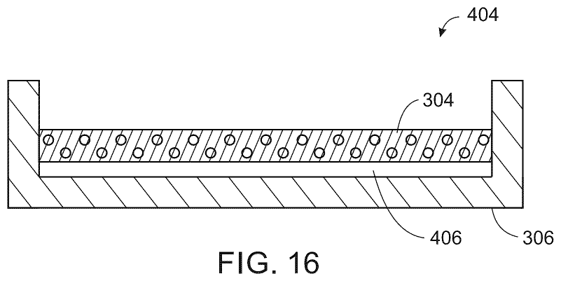

FIG. 16. is a cross-sectional view of an additively manufactured acoustic backing 404 (e.g., with a space between the mold and porous structure). The additively manufactured acoustic backing 404 includes the porous structure 304 as described above in FIG. 4. In certain embodiments, the porous structure 304 and the mold 306 (e.g., solid mold) are printed together as a single part with a gap or space 406 located between the mold 306 and the porous structure 304 (e.g., between the sixth surface 318 of the porous structure 304 and the mold 306). The purpose of this gap 406 is to allow for easier post-processing (cleaning, infiltration, etc.). In certain embodiments, the gap 406 may also be multiple channels. This embodiment can be used with multiple geometries for the porous structure 304 and/or the mold 306.

Technical effects of the disclosed embodiments include providing methods for manufacturing (e.g., additively manufacturing) an acoustic backing of a transducer probe (e.g., an ultrasound probe). In particular, the disclosed embodiments enable the additive manufacturing (e.g., three-dimensional (3D) printing) of an acoustic backing with integrated or built in mold as a single part. The single part is a multi-parameter backing that includes an acoustic attenuation parameter set (i.e., the acoustic backing portion having a porous structure or matrix) and a parameter set with high density but some porosity (in some cases) (i.e., the mold). The single part or multi-parameter backing enables resin (e.g., lossy epoxy) to enter the porous structure during infiltration and to remain within the porous structure during infiltration and between infiltration and curing. Technical effects of the disclosed embodiments also include enabling the utilization of an industrial infiltration system in manufacturing the acoustic backing. Technical effects of the disclosed embodiments further include improving the quality of the additively manufactured acoustic backing. Technical effects of the disclosed embodiments even further include reducing the amount of scrap generated in additively manufacturing acoustic backings (e.g., due to void spaces in the additively manufactured acoustic backings). Technical effects of the disclosed embodiments yet further include enabling the additive manufacturing of the acoustic backings to reduce the chance of a supply chain risk.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

This written description uses examples to disclose the present subject matter, including the best mode, and also to enable any person skilled in the art to practice the subject matter, including making and using any devices or systems and performing any incorporated methods. The patentable scope of the subject matter is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A method for manufacturing an acoustic backing of a transducer probe, comprising:
utilizing three-dimensional (3D) printing to print a single part comprising both a porous structure and a solid structure, wherein the porous structure is disposed within the solid structure, and the porous structure is configured to attenuate acoustic energy;
infiltrating the single part with filler material; and
curing the single part, wherein the single part is configured both to enable both the filler material to enter the porous structure during infiltration and to keep the filler material contained in the porous structure between the infiltration and curing of the single part.

2. The method of claim 1, further comprising removing at least a portion of the solid structure from the porous structure to obtain the acoustic backing via post-processing.

3. The method of claim 1, wherein the porous structure comprises multiple surfaces, and wherein the solid structure covers one or more surfaces of the multiple surfaces of the porous structure leaving at least one surface exposed.

4. The method of claim 3, wherein the solid structure comprises one or more passages extending from an exposed surface of the solid structure to one or more surfaces of the multiple surfaces of the porous structure, wherein the one or more passages are configured to enable the filler material and/or an un-sintered metallic powder to enter the porous structure via the one or more surfaces during infiltration.

5. The method of claim 3, wherein the solid structure covers all but one surface of the multiple surfaces of the porous structure leaving the one surface exposed and a portion of a mold adjacent the one surface extends beyond the one surface in a direction opposite the one surface to create a reservoir for the filler material.

6. The method of claim 3, wherein the porous structure is printed with a spacer that extends between a gap between the porous structure and the solid structure, and wherein the solid structure covers all but one surface of the multiple surfaces of the porous structure leaving the one surface exposed.

7. The method of claim 1, wherein the single part has a complex geometric shape.

8. A method for manufacturing an acoustic backing of a transducer probe, comprising:
utilizing three-dimensional (3D) printing to print a single part comprising both a porous structure and a hybrid porous/solid structure, wherein the porous structure is disposed within the hybrid porous/solid structure, and the porous structure is configured to attenuate acoustic energy;
infiltrating the single part with filler material; and
curing the single part, wherein the single part has variable porosity configured both to enable the filler material to enter the porous structure during infiltration and to keep the filler material contained in the porous structure between the infiltration and curing of the single part.

9. The method of claim 8, further comprising removing at least a portion of the hybrid porous/solid structure from the porous structure to obtain the acoustic backing via post-processing.

10. The method of claim 8, wherein the porous structure comprises multiple surfaces, wherein the hybrid porous/solid structure comprises both a porous portion and a solid portion, and wherein the solid portion of the hybrid porous/solid structure covers all but one surface of the multiple surfaces of the porous structure, and the porous portion of the hybrid porous/solid structure covers the one surface of the porous structure not covered by the solid portion of the hybrid porous/solid structure.

11. The method of claim 10 wherein the porous portion of the hybrid porous/solid structure covering the one surface of the structure has smaller pores than pores of the porous structure.

12. The method of claim 8, wherein the porous structure comprises multiple surfaces, wherein the hybrid porous/solid structure comprises both a porous portion and a solid portion, and wherein the solid portion of the hybrid porous/solid structure covers all but two surfaces of the multiple surfaces of the porous structure, and the porous portion of the hybrid porous/solid structure covers the two surfaces of the porous structure not covered by the solid portion of the hybrid porous/solid structure.

13. The method of claim 12, wherein the two surfaces of the porous structure not covered by the solid portion of the hybrid porous/solid structure are disposed on opposite sides from each other.

14. The method of claim 12, wherein each respective portion of the porous portion of the hybrid porous/solid structure covering the two surfaces of the porous structure not covered by the solid portion of the hybrid porous/solid structure has smaller pores than pores of the porous structure.

15. The method of claim 8, wherein the porous structure has a complex geometric shape.

16. A method for manufacturing an acoustic backing of a transducer probe, comprising:
utilizing three-dimensional (3D) printing to print a single part comprising both a first porous structure and a second porous structure, wherein the first porous structure is disposed within the second porous structure, and the first porous structure is configured to attenuate acoustic energy;
infiltrating the single part with filler material; and
curing the single part, wherein the single part has variable porosity configured both to enable filler material to enter the first porous structure during infiltration and to contain the filler material in the first porous structure between the infiltration and curing of the single part.

17. The method of claim 16, further comprising removing at least a portion of the second porous structure from the first porous structure to obtain the acoustic backing via post-processing.

18. The method of claim 16, wherein the second porous structure covers every surface of the first porous structure.

19. The method of claim 18, wherein each respective portion of the second porous structure covering each respective surface of the first porous structure has smaller pores than pores of the first porous structure.

20. The method of claim 16, wherein the first porous structure has a complex geometric shape.
